(19) United States
(12) Patent Application Publication
(10) Pub. No.: US 2026/0006883 A1
(43) Pub. Date: Jan. 1, 2026

(54) SEMICONDUCTOR DEVICE AND MANUFACTURING METHOD THEREOF

(71) Applicant: Hon Young Semiconductor Corporation, Hsinchu City (TW)

(72) Inventors: Yan-Ru CHEN, Hsinchu City (TW); Chao-Yi CHANG, Hsinchu City (TW)

(21) Appl. No.: 18/811,797

(22) Filed: Aug. 22, 2024

(30) Foreign Application Priority Data
Jun. 28, 2024 (TW) 113124197

(51) Int. Cl. H01L 29/423; H01L 29/417; H01L 29/66; H01L 29/78

(52) U.S. Cl. CPC H10D 64/519; H10D 30/0291; H10D 30/66; H10D 64/252

(57) ABSTRACT

A semiconductor device includes a substrate, a drift region, a channel region, a source region, a gate electrode layer and a gate pad. The drift region is located in the substrate. The gate electrode layer is located above the drift region and is adjacent to the channel region and the source region, in which the gate electrode layer includes a cell area, a connection area and a gate pad area. The cell area at least covers the channel region in the substrate. The connection area is adjacent to the cell area, in which the connection area has at least one opening that penetrates the connection area. The gate pad contacts the gate pad area of the gate electrode layer, in which the gate pad and the at least one opening of the connection area of the gate electrode layer is laterally separated.

### RELATED APPLICATIONS

This application claims priority to Taiwan Application Serial Number 113124197, filed Jun. 28, 2024, which is herein incorporated by reference.

### BACKGROUND

### Field of Invention

The present disclosure relates to a semiconductor device and a manufacturing method of a semiconductor device.

### Description of Related Art

The industry of semiconductor has grown fast recently, which makes the size of semiconductor device gets smaller and smaller, and the speed of switching is faster and faster. When switching rapidly, the parasitic capacitance of gate will significantly affect the speed and the power consumption of switching. Thus, the need of a kind of semiconductor device that can decrease the parasitic capacitance of gate exists.

### SUMMARY

One aspect of the present disclosure provides a semiconductor device.

According to one embodiment of the present disclosure, a semiconductor device includes a substrate, a drift region, a channel region, a source region, a gate electrode layer and a gate pad. The drift region is located in the substrate. The channel region is located in the substrate. The source region is located in the substrate and adjacent to the channel region. The gate electrode layer is located on the drift region and adjacent to the channel region and the source region, in which the gate electrode layer includes a cell area, a connection area and a gate pad area. The cell area at least covers the channel region of the substrate. The connection area is adjacent to the cell area, in which the connection area has at least an opening that penetrates the connection area. The gate pad area, in which the connection area is located between the cell area and the gate pad area. The gate pad contacts the gate pad area of the gate electrode layer, in which the gate pad and the at least one opening of the connection area of the gate electrode layer is laterally separated.

Another aspect of the present disclosure provides a semiconductor device.

According to one embodiment of the present disclosure, a semiconductor device includes a substrate, a channel region, a gate electrode layer and a gate pad. The channel region is located in the substrate, in which the channel region has inside a first doping region and two second doping region. The first doping region is located in the channel region. The two second doping region is located in the channel region and two sides of the first doping region, in which a conductivity type of the first doping region is opposite to a conductivity type of the second doping region. The gate electrode layer is located on the substrate, in which the gate electrode layer includes a cell area, a connection area and a gate pad area. The cell area at least covers the channel region of the substrate. The connection area is adjacent to the cell area, in which the connection area has a plurality of opening that penetrates the connection area, and an area of the openings of the connection area accounts for at least ten percent of a total area of the connection area. The gate pad area, in which the connection area is located between the cell area and the gate pad area. The gate pad contacts the gate pad area of the gate electrode layer.

Another aspect of the present disclosure provides a manufacturing method of a semiconductor device.

According to one embodiment of the present disclosure, a manufacturing method of a semiconductor device includes forming a drift region in a substrate; forming a channel region in the drift region; forming a source region and a body region in the channel region; covering a first dielectric layer on the drift region; covering a conducting layer on the first dielectric layer; patterning the first dielectric layer and the conducting layer to form a gate dielectric layer and a gate electrode layer, in which the gate electrode layer includes a cell area, a connection area and a gate pad area. The cell area at least covering the channel region of the substrate. The connection area is adjacent to the cell area, in which the connection area has at least an opening that penetrates the connection area. The gate pad area, in which the connection area is located between the cell area and the gate pad area.

In the aforementioned embodiments of the present disclosure, since there are openings that penetrates the gate electrode layer at the connection area of the gate electrode layer, the gate-drain capacitance (C_{gd}) can be decrease by decreasing the area of the connection area of the gate electrode layer, thereby decreasing the power consumption of the switching of the semiconductor device and increasing the speed of switching.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device according to one embodiment of the present disclosure.

FIG. 2 is a top view of the gate electrode layer and the gate pad of FIG. 1.

FIG. 3 is a top view of the semiconductor device of FIG. 1.

### DETAILED DESCRIPTION

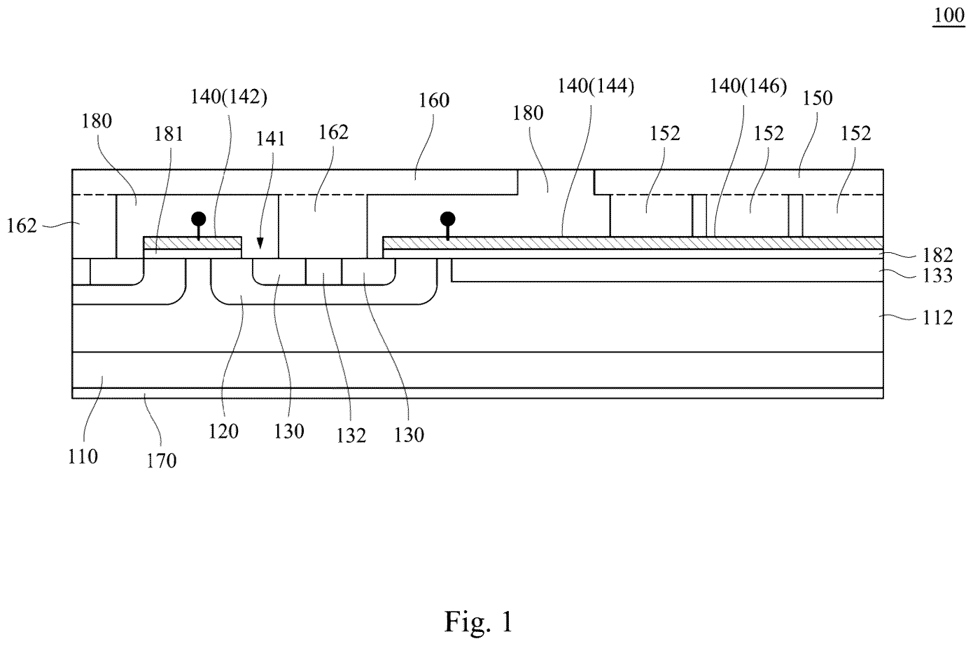

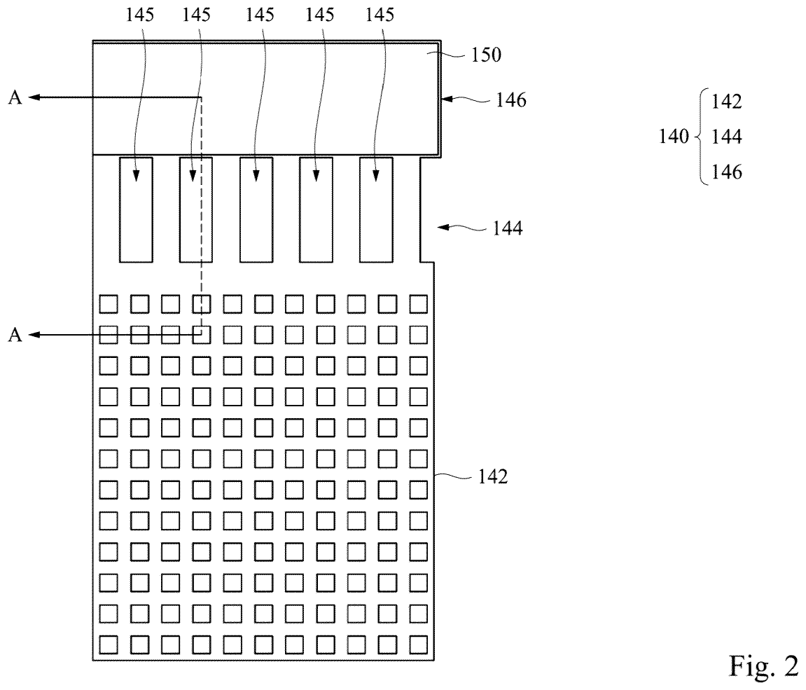

FIG. 1 is a cross-sectional view of a semiconductor device according to one embodiment of the present disclosure. FIG. 2 is a top view of the gate electrode layer and the gate pad of FIG. 1. In detail, FIG. 1 is a cross-sectional view along line A-A of FIG. 2.

Refer to FIG. 1, a semiconductor device 100 includes a substrate 110, a drift region 112, a channel region 120, a source region 130, a gate electrode layer 140 and a gate pad 150. The drift region 112 is located in the substrate 110. The channel region 120 is located in the substrate 110. In some embodiments, the substrate 110 can be a N-doped area. In some embodiments, the conductivity type of the channel region 120 is opposite to the conductivity type of the drift region 112. For example, if the drift region 112 is a N-doped area, then the channel region 120 can be a p-doped area. The source region 130 is located in the substrate 110 and adjacent to the channel region 120. The conductivity type of the source region is opposite to the conductivity type of the channel region 120. For example, if the channel region 120 is a p-doped area, then the source region 130 can be a N-doped area. It is shown that there are two source regions 130 in FIG. 1, but the disclosure is not limited to this. Moreover, there is a body region 132 between two source regions 130. The conductivity type of the body region 132 is opposite to the conductivity type of the source region 130. For example, if the source region 130 is a p-doped area, then the body region 132 can be a N-doped area.

In some embodiments, the doping concentration of the substrate 110 and the source region 130 (such as N+ region) is greater than the doping concentration of the drift region 112 (such as N-region). In some embodiments, the doping concentration of the body region 132 (such as P+ region) is greater than the doping concentration of the channel region 120 (such as P region).

Please refer to FIG. 1 and FIG. 2, the gate electrode layer 140 is located on the drift region 112 and adjacent to the channel region 120 and the source region 130, in which the gate electrode layer 140 includes a cell area 142, a connection area 144 and a gate pad area 146. The cell area 142 at least covers the channel region 120 of the substrate 110. The connection area 144 is adjacent to the cell area 142, in which the connection area 144 has at least an opening 145 that penetrates the connection area 144. In FIG. 2, the openings are shown to be five, but the disclosure is not limited to this. The connection area 144 is located between the cell area 142 and the gate pad area 146. In some embodiments, from a top view (such as FIG. 2) each of the openings 145 has a rectangular contour, in which the four sides of the contour is defined by the material of the gate electrode layer. In some embodiments, the material of the gate electrode layer can include conducting material, such as metal or poly silicon, but the disclosure is not limited to this.

The semiconductor device further includes a gate dielectric layer 181 and a dielectric layer 182. In some embodiments, the gate dielectric layer is located between the cell area 142 of the gate electrode layer 140 and the substrate 110, and the dielectric layer 182 is located between the connection area 144 and the gate pad area 146 of the gate electrode layer 140 and the substrate 110. In some embodiments, the gate dielectric layer 181 and the cell area 142 of the gate electrode layer 140 can be collectively call gate structure. In some embodiments, the material of the gate dielectric layer 181 and the dielectric layer 182 can include dielectric material. Such as silicon dioxide (SiO₂), aluminum oxide (Al₂O₃) or other suitable material, but not limited to this.

The gate pad 150 electrically connects the gate pad area 146 of the gate electrode layer 140, in which the gate pad 150 and the at least one opening 145 of the connection area 144 of the gate electrode layer 140 is laterally separated. In another aspect, the projection of the gate pad 150 on the substrate 110 and the projection of the opening 145 of the connection area 144 of the gate electrode layer 140 on the substrate don't overlap. In some embodiments, the material of the gate pad can include metal, but not limited to this.

As shown in FIG. 1, the substrate 110 includes a P-doped area 133 inside. The dopant and the doping concentration of the P-doped area 133 is similar to the body region 132. However, unlike the body region 132, the P-doped area 133 directly contacts the drift region 112. In other words, there is no channel region 120 between the P-doped area 133 and the drift region 112 of the substrate 110. Moreover, the P-doped area 133 is located under the connection area 144 and the gate pad area 146.

Since there are openings 145 that penetrates the gate electrode layer 140 at the connection area 144 of the gate electrode layer 140, the gate-drain capacitance (C_{gd}) can be decrease by decreasing the area of the connection area 144 of the gate electrode layer 140, thereby decreasing the power consumption of the switching of the semiconductor device 100 and increasing the speed of switching.

In some embodiments, an area of the opening 145 of the connection area 144 accounts for at least ten percent of a total area of the connection area 144. In some embodiments, an area of the opening 145 of the connection area 144 accounts for about ten percent to about twenty five percent of a total area of the connection area 144. For example, it can be ten present, or twenty present, or twenty five present. In some embodiments, a shape of the opening 145 of the connection area 144 can be a quadrilateral, a circle, a triangle and a polygon. For example, it can be a pentagon, a hexagon; the shape will not affect the embodiment of the disclosure. Moreover, the cell area 142 of the gate electrode layer 140 has a second opening 141 that penetrate the cell area 142, and the second opening expose the body region 132 and the source region 130 on a vertical direction.

Moreover, the semiconductor device further includes at least one first metal through hole 152. The first metal through hole 152 is located between the gate pad area 146 of the gate electrode layer 140 and the gate pad 150, and electrically connects the gate pad area 146 of the gate electrode layer 140 and the gate pad 150. The semiconductor device further includes a source contact pad 160 and at least a second metal through hole 162. The source contact pad 160 is located on the source region 130 and the cell area of the gate electrode layer 140 and electrically connects the source region 130. The second metal through hole 162 is located between the source contact pad 160 and the source region 130 and electrically connects the source contact pad 160 and the source region 130. In some embodiments, the two boarders of the connection area 144 can be the right boarder of the second opening 141 of the cell area 142 and is closest to the gate pad area 146 and the left boarder of the first metal through hole 152 that is closest to the cell area 142. Moreover, the semiconductor device further includes a drain pad 170. The drain pad 170 is located on a side of the substrate 110 opposite to the gate electrode layer 140. In some embodiments, the material of the first metal through hole 152, the second metal through hole 162 and the source contact pad can include metal, such as copper, but not limited to this.

Moreover, the semiconductor device further includes a dielectric layer 180. The dielectric layer 180 covers the gate electrode layer 140. In some embodiments, the dielectric layer 180 extends to the sidewall of the gate electrode layer 140, the gate dielectric layer and the dielectric layer to electrically isolate the first metal through hole 152, the second metal through hole 162 and the gate electrode layer 140. The material of the dielectric layer 180 can be silicon dioxide (SiO₂) of other suitable dielectric material.

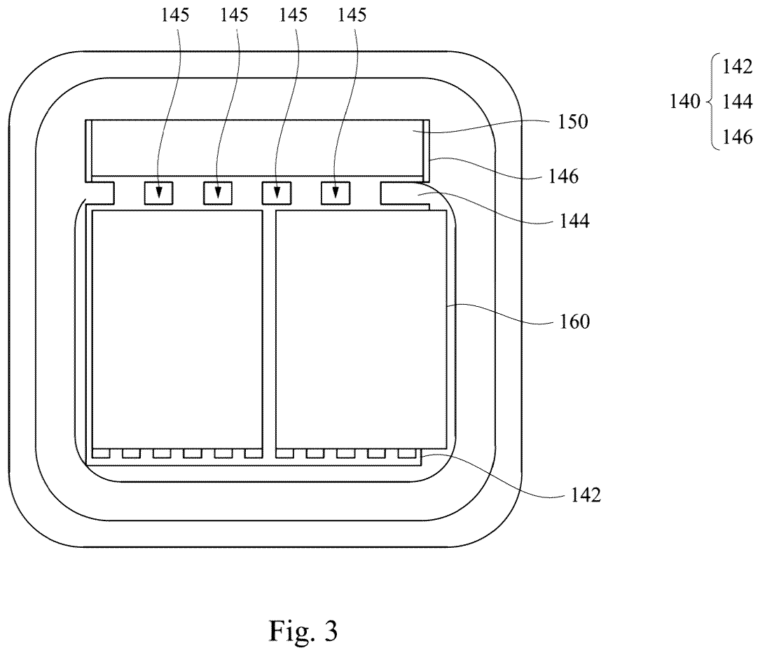

FIG. 3 is a top view of the semiconductor device of FIG. 1. Refer to FIG. 3, after the source contact pad 160 and the gate pad 150 of the semiconductor device 100 is disposed, the cell area 142 will be covered by the source contact pad 160. Below them is filled with multiple metal-oxide-semiconductor field-effect transistor (MOSFET) of other suitable components. The source of these components will controlled by the source contact pad 160 that electrically connect the source region 130 (see FIG. 1), and the gate of these components will controlled by the gate electrode layer 140 that connects to the gate pad 150. After packaging, the source contact pad 160 and the gate pad 150 will contact to external circuit (such as using solder reflow to connect to external circuit, but the disclosure is not limited to this.) Since openings 145 are added to the connection area 144 between the source contact pad 160 and the gate pad 150, the gate-drain capacitance (C_{gd}) of this section can be decrease, thereby decreasing the power consumption of the switching of the semiconductor device 100 and increasing the speed of switching.

In the following description, the manufacturing method of semiconductor device 100 is described.

Refer to FIG. 1, first, forming a drift region 112 in a substrate 110. Then, forming a channel region 120 in the drift region 112. The channel region 120 can use diffusion or ion implantation, or any suitable method. Then, forming a source region 130 and a body region 132 in the channel region. The forming of the source region 130 and the body region 132 can be diffusion of ion implantation, or any suitable method. Then, covering a first dielectric layer on the drift region 112. The material of the first dielectric layer can include dielectric material, such as silicon dioxide (SiO₂), aluminum oxide (Al₂O₃) or other suitable material, but not limited to these. Then, covering a conducting layer on the first dielectric layer. The material of the conducting layer can include conducting material, such as poly silicon or metal, but not limited to these. Then, patterning the first dielectric layer and the conducting layer to form a gate dielectric layer 181, the dielectric layer 182 and a gate electrode layer 140, in which the gate electrode layer includes a cell area 142, a connection area 144 and a gate pad area 146. The cell area 142 at least covering the channel region 120 of the substrate 110. The connection area 144 is adjacent to the cell area 142, in which the connection area 144 has at least an opening 145 that penetrates the connection area 144. The gate pad area 146, in which the connection area 144 is located between the cell area 142 and the gate pad area 146.

Then, coating a second dielectric layer 180 on the gate electrode layer 140. Patterning the second dielectric layer 180 to form a plurality of openings. Depositing metal in the openings to form at least one first metal through hole 152 and at least one second metal through hole 162. Then, forming a source contact pad 160 and a gate pad 150. Last, forming a drain pad 170 on a side of the substrate 110 opposite to the drift region 112.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a drift region located in the substrate;
a channel region located in the substrate;
a source region located in the substrate and adjacent to the channel region;
a gate electrode layer located on the drift region and adjacent to the channel region and the source region, wherein the gate electrode layer comprises:
a cell area at least covering the channel region of the substrate;
a connection area adjacent to the cell area, wherein the connection area has at least an opening that penetrates the connection area; and
a gate pad area, wherein the connection area is located between the cell area and the gate pad area; and
a gate pad contacting the gate pad area of the gate electrode layer, wherein the gate pad and the at least one opening of the connection area of the gate electrode layer is laterally separated.

2. The semiconductor device of claim 1, wherein an area of the opening of the connection area accounts for at least ten percent of a total area of the connection area.

3. The semiconductor device of claim 1, wherein a shape of the opening of the connection area is at least one of a quadrilateral, a circle, a triangle and a polygon.

4. The semiconductor device of claim 1, further comprising:
a body region adjacent to the source region, wherein a conductivity type of the body region is opposite to a conductivity type of the source region.

5. The semiconductor device of claim 1, further comprising:
a source contact pad located on the source region and the cell area of the gate electrode layer, electrically connected to the source region.

6. The semiconductor device of claim 1, further comprising:
a drain pad located on a side of the substrate opposite to the gate electrode layer.

7. A semiconductor device, comprising:
a substrate;
a channel region located in the substrate, wherein the channel region has inside:
a first doping region located in the channel region; and
two second doping region located in the channel region and two sides of the first doping region, wherein a conductivity type of the first doping region is opposite to a conductivity type of the second doping region;
a gate electrode layer located on the substrate, wherein the gate electrode layer comprises:
a cell area at least covering the channel region of the substrate;
a connection area adjacent to the cell area, wherein the connection area has a plurality of opening that penetrates the connection area, and an area of the openings of the connection area accounts for at least ten percent of a total area of the connection area; and
a gate pad area, wherein the connection area is located between the cell area and the gate pad area; and
a gate pad contacting the gate pad area of the gate electrode layer.

8. The semiconductor device of claim 7, further comprising:
a source contact pad located on the second doping region and the cell area of the gate electrode layer, electrically connected to the second doping region; and
at least one first metal through hole located between the second doping region and the source contact pad, electrically connected to the second doping region and the source contact pad.

9. The semiconductor device of claim 7, wherein the gate pad and the openings of the connection area of the gate electrode layer is laterally separated.

10. The semiconductor device of claim 7, wherein a shape of the opening of the connection area is at least one of a quadrilateral, a circle, a triangle and a polygon.

11. The semiconductor device of claim 7, further comprising:
a dielectric layer surrounding the cell area and the connection area of the gate electrode layer.

12. The semiconductor device of claim 11, wherein the dielectric layer has a portion extends between the gate pad area of the gate electrode layer and the substrate.

13. The semiconductor device of claim 7, further comprising:
at least one second metal through hole located between the gate pad area of the gate electrode layer and the gate pad, electrically connected to the gate pad area of the gate electrode layer and the gate pad.

14. The semiconductor device of claim 7, further comprising:
a gate dielectric layer under the cell area of the gate electrode layer.

15. A manufacturing method of a semiconductor device, comprising:
forming a drift region in a substrate;
forming a channel region in the drift region;
forming a source region and a body region in the channel region;
covering a first dielectric layer on the drift region;
covering a conducting layer on the first dielectric layer;
patterning the first dielectric layer and the conducting layer to form a gate dielectric layer and a gate electrode layer, wherein the gate electrode layer comprises:
a cell area at least covering the channel region of the substrate;
a connection area adjacent to the cell area, wherein the connection area has at least an opening that penetrates the connection area; and
a gate pad area, wherein the connection area is located between the cell area and the gate pad area.

16. The manufacturing method of the semiconductor device of claim 15, further comprising:
coating a second dielectric layer on the gate electrode layer;
patterning the second dielectric layer to form a plurality of openings; and
depositing metal in the openings to form at least one first metal through hole and at least one second metal through hole.

17. The manufacturing method of the semiconductor device of claim 16, further comprising:
forming a source contact pad and a gate pad on the at least one first metal through hole and the at least one second metal through hole.

18. The manufacturing method of the semiconductor device of claim 15, further comprising:
forming a drain pad on a side of the substrate opposite to the drift region.
